(19) United States
(12) Patent Application Publication
(10) Pub. No.: US 2014/0185238 A1
(43) Pub. Date: Jul. 3, 2014

(54) CHASSIS OF ELECTRONIC DEVICE

(71) Applicants: HONG FU JIN PRECISION INDUSTRY (ShenZhen) CO., LTD., (US); HON HAI PRECISION INDUSTRY CO., LTD., New Taipei (TW)

(72) Inventors: XIAN-XIU TANG, Shenzhen (CN); CHIA-SHIN CHOU, New Taipei (TW)

(73) Assignees: HON HAI PRECISION INDUSTRY CO., LTD., New Taipei (TW); HONG FU JIN PRECISION INDUSTRY (ShenZhen) CO., LTD., Shenzhen (CN)

(21) Appl. No.: 13/759,052

(22) Filed: Feb. 5, 2013

(30) Foreign Application Priority Data
Dec. 27, 2012 (CN) 201210577922.X

(51) Int. Cl. H05K 7/20

(52) U.S. Cl. CPC H05K 7/20
USPC 361/692

(57) ABSTRACT

A cover of a chassis includes a board defining an opening, and a vent plate slidably mounted to the board and covering the opening. The vent plate defines a number of vents. The vent plate can be slid to adjust the vents to align with or stagger from the opening.

### BACKGROUND

1. Technical Field

The present disclosure relates to a chassis of an electronic device.

2. Description of Related Art

Some servers can generate great heat after a certain period of time, especially if electronic elements, such as expansion cards or memory cards, are added to the servers. As a result, the original heat dissipation system may not dissipate the heat competently.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of an embodiment of a chassis, wherein the chassis includes a cover.

FIG. 2 is an exploded, isometric view of the cover of FIG. 1, but viewed from an inverted perspective.

FIG. 3 is an enlarged view of the circled portion III of FIG. 2.

FIG. 4 is an enlarged view of the circled portion IV of FIG. 1.

FIG. 5 is an assembled, isometric view of FIG. 1.

FIG. 6 is a cross-sectional view of FIG. 5, taken along the line VI-VI.

FIG. 7 is similar to FIG. 5, but showing another using state.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

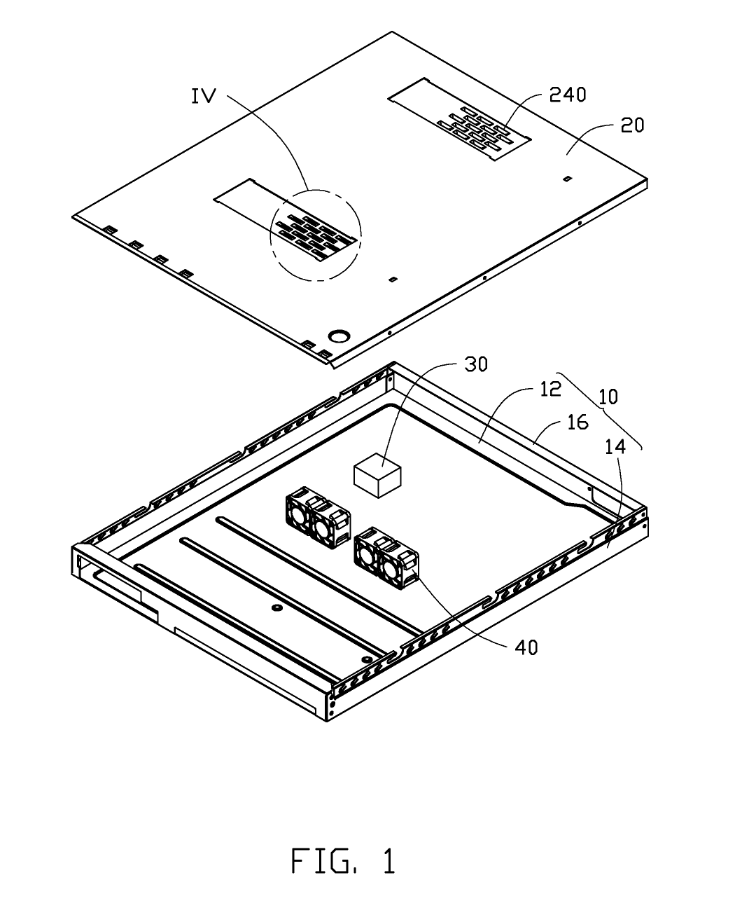

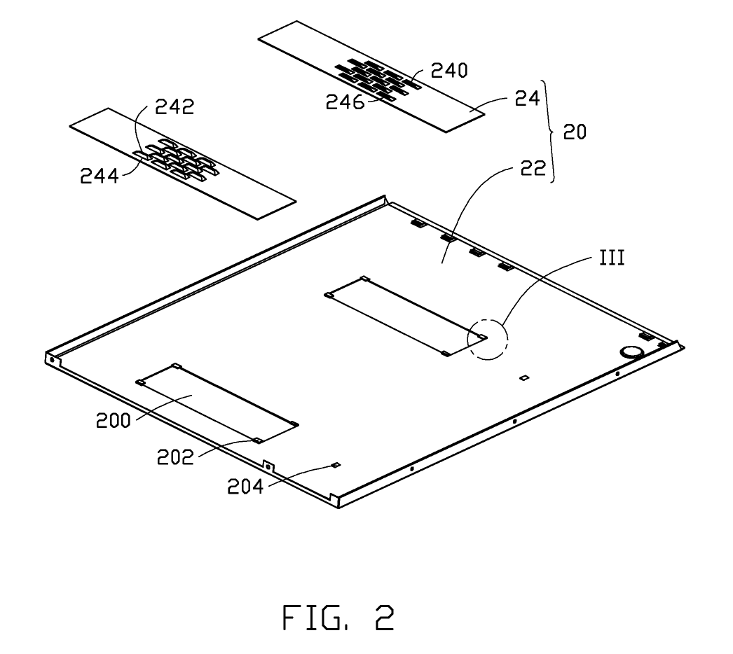

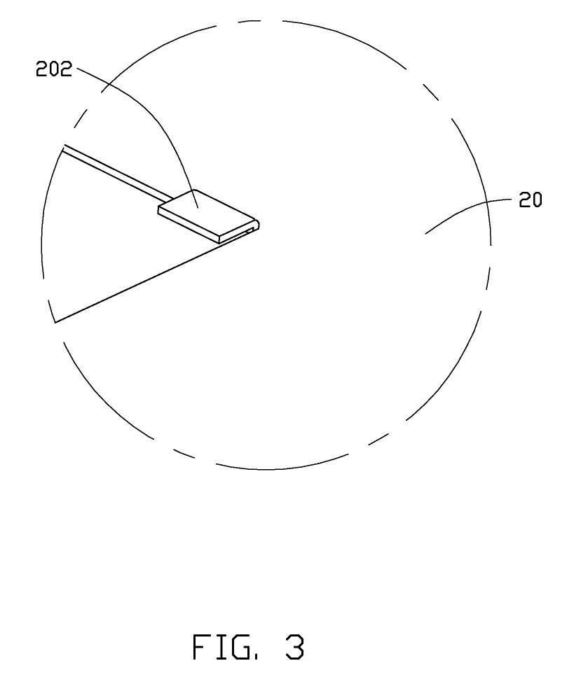

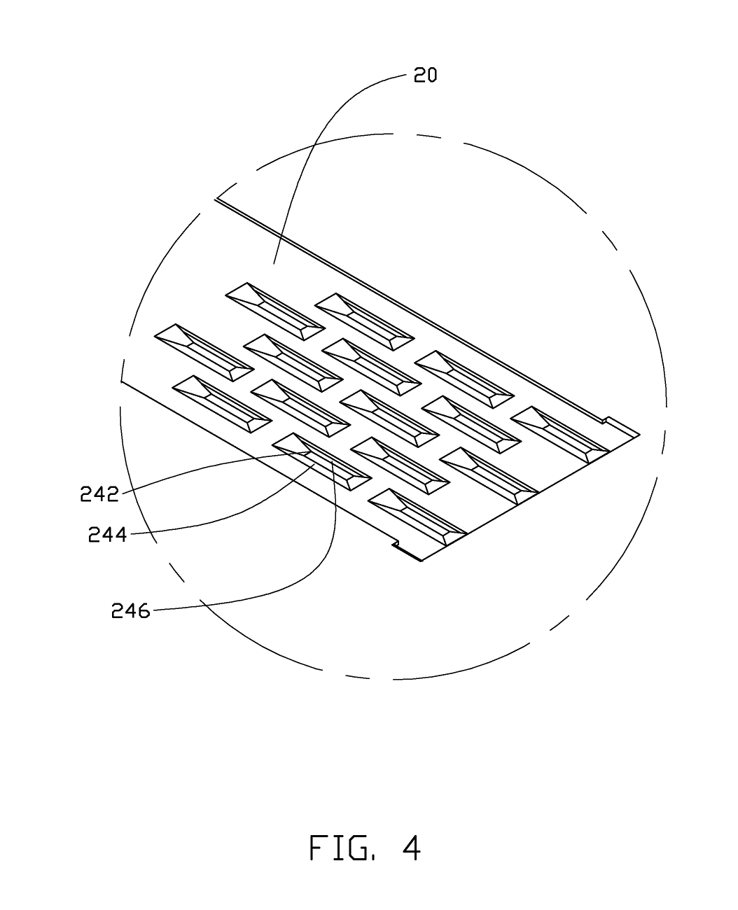

FIGS. 1 to 4 show an embodiment of a chassis of an electronic device. In this embodiment the electronic device is a server. The server includes a base 10, a cover 20, an electronic element 30 generating heat, and a fan group 40 including a plurality of fans to dissipate the heat generated by the electronic element 30.

The base 10 includes a bottom wall 12, two sidewalls 14 connected substantially perpendicularly to opposite sides of the bottom wall 12, and two end walls 16 connected substantially perpendicularly to opposite ends of the bottom wall 12.

The electronic element 30 and the fan group 40 are mounted on the bottom wall 12. In one embodiment, the electronic element 30 is a central processing unit.

The cover 20 includes a board 22 and two rectangular vent plates 24.

The board 22 defines two rectangular openings 200, adjacent to opposite ends of the board 22. Two L-shaped hooks 202 extend from the bottom surface of the board 22, at opposite sides of each opening 200 and facing toward the corresponding opening 200. A block 204 protrudes from the bottom surface of the board 22, adjacent to an end of each opening 200.

Each vent plate 24 is greater than the openings 200 in length, and defines a plurality of tapered depressed portions 240 in a center. Each depressed portion 240 includes a rectangular bottom plate 242 less than the opening 200 inside and departing from the vent plate 24, and four slanted side plates 244 slantingly connected between sidewalls bounding the opening 200 and corresponding sides of the bottom plate 242. A plurality of vents 246 is defined in side plates 244 of the depressed portions 240 facing a same side of the vent plate 24.

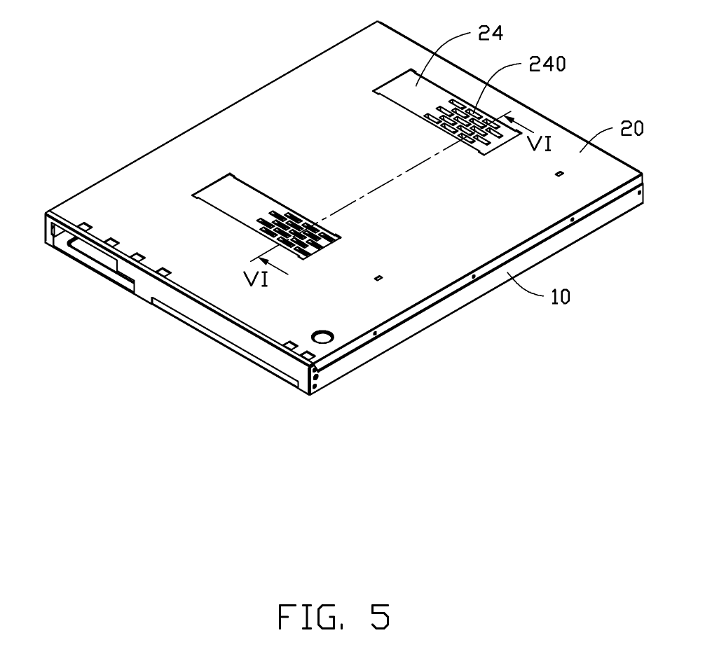

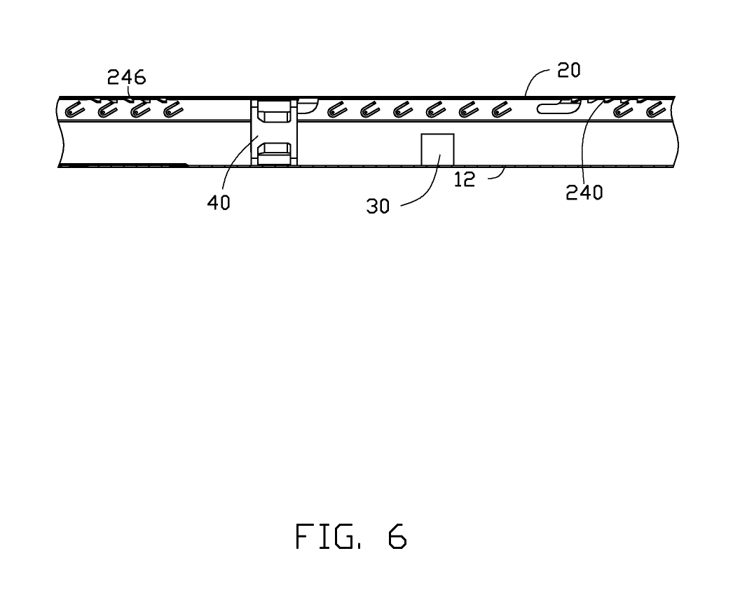

FIGS. 5 and 6 show that in assembly, each vent plate 24 is slidably mounted to the bottom surface of the board 22 between the hooks 202 and the board 22 at one of the openings 200, from an end of the opening 200 opposite to the corresponding block 204, to cover the opening 200. The vent plate 24 can be slid to adjust the vents 246 to align with the corresponding opening 200. The vents 246 of one of the vent plate 24 face toward the vents 246 of the other vent plate 24.

The cover 20 is then mounted to the base 10. The vent plates 24 are positioned at opposite sides of the fan group 40, and are respectively adjacent to the inlet and the outlet of the fan group 40. Therefore, more airflow can enter the chassis. One of the vent plates 24 is positioned above the electronic element 30. The vents 246 all face toward the fan group 40. Therefore, the cool airflow can rapidly enter the chassis through the vents 246 located at the inlet of the fan group 40. In addition, the hot airflow from the electronic component 30 can rapidly flow out of the chassis through the vents 246 located at the outlet of the fan group 40.

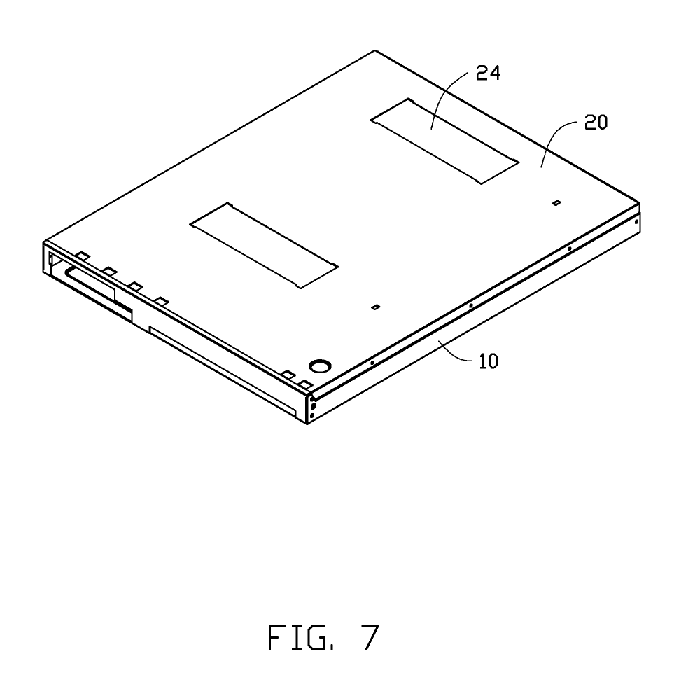

FIG. 7 shows that in case of nonuse, the vent plates 24 can be slid to completely cover the corresponding openings 200, and the vents 246 are staggered from the corresponding openings 200 and are located below the board 22. The blocks 204 can block the vent plates 24, to prevent the vent plates 24 from disengaging from the hooks 202.

It is believed that the present embodiments and their advantages will be understood from the foregoing description, and various changes may be made thereto without departing from the spirit and scope of the description or sacrificing all of their material advantages, the examples hereinbefore described merely being exemplary embodiments.

What is claimed is:

1. A cover of a chassis, comprising:
a board defining an opening therein; and
a vent plate sildably mounted to the board and covering the opening, the vent plate defining a plurality of vents aligning with or staggered from the opening accompanying the sliding of the vent plate.

2. The cover of claim 1, wherein the vent plate defines a plurality of depressed portions, each depressed portion comprises a bottom plate departing from the vent plate, and a plurality of slanted side plates connected between sidewalls bounding the opening and corresponding sides of the bottom plate, the plurality of vents being defined in the side plates of the depressed portions.

3. The cover of claim 2, wherein the plurality of vents is defined in the side plates facing a same side of the vent plate.

4. The cover of claim 1, further comprising two L-shaped hooks extending from the board at opposite sides of the opening and facing toward the opening, wherein the vent plate is slidably engaged between the hooks.

5. The cover of claim 1, further comprising a block protruding from the board and adjacent to an end of the opening.

6. A chassis, comprising:
a base;
an electronic element mounted in the base;
a fan mounted in the base and adjacent to the electronic device, the fan having an inlet and an outlet; and
a cover comprising a board defining two openings, and two vent plates sildably mounted to the board and covering the corresponding openings, wherein the vent plates are respectively adjacent to the outlet and the inlet of the fan; each vent plate defines a plurality of vents aligned with or staggered from the corresponding opening accompanying the sliding of the vent plate.

7. The chassis of claim 6, wherein each vent plate defines a plurality of depressed portions, each depressed portion comprises a bottom plate departing from the vent plate, and a plurality of slanted side plates connected between sidewalls bounding the corresponding opening and corresponding sides of the bottom plate, the plurality of vents of each vent plate being defined in the side plates of the depressed portions.

8. The chassis of claim 7, wherein the plurality of vents of each vent plate are defined in the side plates facing a same side of the vent plate.

9. The chassis of claim 7, wherein the side plates defining the plurality of vents face the fan.

10. The chassis of claim 6, further comprising two substantially L-shaped hooks extending from the board at opposite sides of each opening and facing toward the opening, wherein each vent plate is slidably engaged between the corresponding hooks.

11. The chassis of claim 6, further comprising a block protruding from the board and adjacent to an end of each opening.
